(19) United States
(12) Patent Application Publication
(10) Pub. No.: US 2012/0161790 A1
(43) Pub. Date: Jun. 28, 2012

(54) NOx SENSING MATERIALS AND SENSORS INCORPORATING SAID MATERIALS

(76) Inventors: Peter Smith, Oxford (GB); Leon Cavanagh, Loughrea (IE)

(21) Appl. No.: 12/975,677

(22) Filed: Dec. 22, 2010

(51) Int. Cl. G01N 27/00; B05D 5/12; G01R 27/08; G01R 27/26; G01N 31/00; B01J 23/02

(52) U.S. Cl. 324/658; 252/408.1; 502/340; 422/83; 422/98; 324/693; 427/126.6

(57) ABSTRACT

Gas-sensitive materials are disclosed which are mixtures or composites of BaSnO₃, and another component comprising one or more phases from the group: CuO, Cr₂O₃, Fe₂O₃, MnO, NiO, CoO, Bi₂O₃, Sb₂O₃, Sb₂O₅, WO₃, ZnO, and SnO₂. The mixture may be modified further by the addition in a highly dispersed manner of fine (less than about 20 nm) particulates of precious metals (Pt, Pd, Au, Ag) to enhance performance. Advantages include: (a) sensitivity in the range 1-2500 ppm NOx typical of combustion environments, (b) reduced humidity influence, (c) repeatability and reliability, and (d) baseline stability over time. In one embodiment, the material includes a mixture of BaSnO₃ and CuO such that CuO is present at 25-50 mol %.

### FIELD OF THE INVENTION

The techniques disclosed herein relate to NOx sensing.

### BACKGROUND OF THE INVENTION

Accurate detection and measurement of gases is highly desirable for many reasons, including health and safety, environmental monitoring, and energy saving. However, it is not a straightforward task.

The current drive to make leaner engines and curtail harmful emissions has demanded the development of new exhaust gas sensors. At present, the technology underpinning such sensors is referred to as solid-state electrochemistry. This technology has delivered two oxygen sensors, the lambda and the broadband sensors, which are a main feature of automotive engines, but the adoption of an electrochemical NOₓ sensor for control of engine emissions has not been widespread. A complicated construction, the associated high unit costs and signal drift may by partly responsible for this. Non-Dispersive Infra-Red (NDIR) provides an alternative gas sensing technology. This optical method can be quite accurate and selective but is unsuited for use in hot, hazardous and dusty conditions such as encountered in combustion environments.

Therefore much attention has been focused over the last few decades on the use of metal oxide-semiconducting (MOS) gas sensors. The basic principle of operation is the induction or transduction of a small change in electrical characteristics (conductivity, permittivity, or spectral impedance) of the material (either as a porous coating or a thin film), in response to the ingress/absorption/adsorption of the target gas. These MOS sensors have inherent advantages of being smaller, long-life, low maintenance, and inexpensive, as well as the capability of greater integration of functionality, so that production is more automated. Greater integration also generally results in lower power, due to reduced parasitic capacitances, important for battery-operated applications. These oxide materials can be deposited on ceramic or plastic substrates to operate as stand-alone component sensors, where the conditioning electronics are in a separate chip, ASIC, or module (“two-chip” or module gas-sensor system). Alternatively the oxide materials may be deposited or formed on a silicon MEMS, silicon-on-insulator (SOI) or SiC substrates, which may also contain some or all of the signal-processing circuitry to condition the output of the sensor (“single-chip” gas-sensor).

There have been some market successes in particular in automotive cabin air quality where MOS sensors are deployed to sense for pollution gases (CO, NOx) and in residential alarms for detecting CO and methane gas. However broader success of MOS gas sensors in the marketplace has been limited due to a variety of reasons—performance issues related to material stability, baseline drift, and cross-sensitivity of the sensor material to other non-target gases and humidity.

Many attempts have been cited in the literature on the deployment of MOS sensors in combustion atmosphere. The use of n-type homogenised BaSnO₃ has been described and the use of SrTi₁₋ₓFeₓO_{3-δ} to detect oxygen changes has been described. Others have focussed on NOₓ detection describing the use of nanoparticulate BaₓWO_{y} or nanocrystalline doped-CeO₂ while others have focussed on p-type materials for sensing combined CO and Oxygen. To date, commercial success in combustion environments has eluded MOS sensors.

This techniques disclosed herein are directed to providing an improved NOx sensing material and sensor.

### SUMMARY OF THE INVENTION

Disclosed herein are gas-sensitive materials which are mixtures or composites of BaSnO₃, and another component comprising one or more phases from the group: CuO, Cr₂O₃, Fe₂O₃, MnO, NiO, CoO, Bi₂O₃, Sb₂O₃, Sb₂O₅, WO₃, ZnO, and SnO₂. The mixture may be modified further by the addition in a highly dispersed manner of fine (less than 20 nm) particulates of precious metals (Pt, Pd, Au, Ag) to enhance performance. Advantages include:

(a) sensitivity in the range 1-2500 ppm NOx typical of combustion environments,

(b) reduced humidity influence,

(c) repeatability and reliability, and/or

(d) baseline stability over time.

Although not restricted to theoretical explanations, the advantageous gas sensing behaviour may be due to gas interaction on the n-p or n-n heterojunctions formed at the boundaries between the primary and the secondary phases.

According to the techniques disclosed herein, there is provided a gas-sensitive material for detecting NOₓ, the material comprising 45 mol % to 95 mol % of BaSnO₃, and 5 mol % to 55 mol % of an oxide from the group CuO, Cr₂O₃, Fe₂O₃, MnO, NiO, CoO, Bi₂O₃, Sb₂O₃, Sb2O5, and WO₃, ZnO, and SnO₂.

In one embodiment, the material comprises 0 to 10 wt % of dopants from the group Pt, Pd, Ag, Au or their compounds.

In one embodiment, the material comprises a catalytically active oxide or precious metal material to provide increased stability and additional protection against nuisance gases.

In one embodiment, the material comprises Pt at approximately 0.01 to 10 wt %.

In one embodiment, the material includes a mixture of BaSnO₃ and CuO such that CuO is present at 25-50 mol %.

In one embodiment, preferably the material has grain sizes in the nano-particulate range of 1 to 400 nm or in the micro particulate range of 0.4 μm-40 μm.

In another aspect, the techniques disclosed herein provide a NOx-detecting transducer comprising a heating element, and a sense element upon which is disposed a gas sensitive material as a thick or thin film open to the atmosphere, said material comprising 45 mol % to 95 mol % of BaSnO₃, and 5 mol % to 55 mol % of an oxide from the group CuO, Cr₂O₃, Fe₂O₃, MnO, NiO, CoO, Bi₂O₃, Sb₂O₃, Sb₂O₅, and WO₃.

In one embodiment, the sense elements are configured as a co-planar array of interdigitated fingers with the gas-sensitive material coated thereupon.

In one embodiment, the transducer further comprises a micro-hotplate substrate, or a silicon-on-insulator, or a SiC substrate, or an oxide ceramic substrate.

In one embodiment, the sense elements are configured as a co-planar array of interdigitated fingers with a spacing in the range of 60 μm to 70 μm.

In one embodiment, the gas-sensitive coating is screen-printed to a thickness in the range of 140 μm to 160 μm.

In one embodiment, the sense element includes gold or another precious metal.

In one embodiment, the heating element comprises platinum.

In another aspect, the techniques disclosed herein provide a method for detecting changes in NO concentration in a reducing atmosphere in the range 1 to 2500 ppm NOₓ, the method comprising contacting the atmosphere with a gas-sensitive material as defined above in any embodiment; and measuring changes in the conductivity, resistance, capacitance, or impedance of said sense element.

In one embodiment, the sense element has an operating temperature in the range 100° C. to 700° C., preferably 500° C. to 650° C. for engine exhaust environments and preferably 100° C. to 400° C. for gas-fuelled heating exhaust environments.

In one embodiment, the environment is an exhaust from a combustion engine.

In one embodiment, the gas-sensitive material is deposited upon the sense elements by a technique selected from screen-printing, stencil printing, spin-coating, sputtering, and ink-jet printing.

In yet another embodiment, there is provided a NOx gas sensor comprising a transducer comprising a heating element, and a sense element upon which is disposed a gas sensitive material as a thick or thin film open to the atmosphere, said material comprising 45 mol % to 95 mol % of BaSnO₃, and 5 mol % to 55 mol % of an oxide from the group CuO, Cr₂O₃, Fe₂O₃, MnO, NiO, CoO, Bi₂O₃, Sb₂O₃, Sb₂O₅, and WO₃. The sensor may further comprise a drive interface adapted to provide a voltage across said sense element, a sense interface adapted to monitor an electrical parameter of the sense element, and a processor adapted to process the monitored parameter.

In one embodiment, a gas-sensitive material may be produced in any suitable manner by combining BaSnO₃ with any one or more of CuO, Cr₂O₃, Fe₂O₃, MnO, NiO, CoO, Bi₂O₃, Sb₂O₃, Sb₂O₅, WO₃, ZnO, and/or SnO₂ and optionally other materials described herein under suitable conditions.

In one respect, disclosed herein is a gas-sensitive material for detecting NO_{R}, the material comprising: from about 45 mol % to about 95 mol % of BaSnO₃, and from about 5 mol % to about 55 mol % of one or more oxides, the one more oxides comprising at least one of CuO, Cr₂O₃, Fe₂O₃, MnO, NiO, CoO, Bi₂O₃, Sb₂O₃, Sb₂O₅, WO₃, ZnO, SnO₂, or any combination thereof.

In another respect disclosed herein is a NOx-detecting transducer comprising a heating element, and a sense element upon which is disposed a gas sensitive material as a thick or thin film open to the atmosphere, said gas sensitive material comprising: from about 45 mol % to about 95 mol % of BaSnO₃, and from about 5 mol % to about 55 mol % of one or more oxides, the one more oxides comprising at least one of CuO, Cr₂O₃, Fe₂O₃, MnO, NiO, CoO, Bi₂O₃, Sb₂O₃, Sb₂O₅, WO₃, ZnO, SnO₂, or any combination thereof.

In another respect, disclosed herein is a method for detecting changes in NOₓ concentration in an atmosphere with a transducer, the method comprising: providing a transducer comprising a heating element, and a sense element upon which is disposed a gas sensitive material as a thick or thin film open to the atmosphere; contacting the atmosphere with the gas-sensitive material of the transducer; and measuring changes in at least one of the conductivity, resistance, capacitance, or impedance of said sense element. The gas sensitive material may comprise from about 45 mol % to about 95 mol % of BaSnO₃, and from about 5 mol % to about 55 mol % of one or more oxides, the one more oxides comprising at least one of CuO, Cr₂O₃, Fe₂O₃, MnO, NiO, CoO, Bi₂O₃, Sb₂O₃, Sb₂O₅, WO₃, ZnO, SnO₂, or any combination thereof.

In another respect, disclosed herein is a method for preparing a NOx-detecting transducer, comprising: providing a heating element and a sense element for the transducer; and depositing gas-sensitive material upon the sense element by a technique that comprises at least one of screen-printing, stencil printing, spin-coating, sputtering, ink-jet printing, or any combination thereof. The gas sensitive material may comprise from about 45 mol % to about 95 mol % of BaSnO₃, and from about 5 mol % to about 55 mol % of one or more oxides, the one more oxides comprising at least one of CuO, Cr₂O₃, Fe₂O₃, MnO, NiO, CoO, Bi₂O₃, Sb₂O₃, Sb₂O₅, WO₃, ZnO, SnO₂, or any combination thereof.

In another respect, disclosed herein is a NOx gas sensor comprising: a transducer comprising a heating element and a sense element upon which is disposed a gas sensitive material as a thick or thin film open to the atmosphere; a drive interface adapted to provide a voltage across said sense element; a sense interface adapted to monitor an electrical parameter of the sense element; and a processor adapted to process the monitored parameter. The gas sensitive material may comprise from about 45 mol % to about 95 mol % of BaSnO₃, and from about 5 mol % to about 55 mol % of one or more oxides, the one more oxides comprising at least one of CuO, Cr₂O₃, Fe₂O₃, MnO, NiO, CoO, Bi₂O₃, Sb₂O₃, Sb₂O₅, WO₃, ZnO, SnO₂, or any combination thereof.

### BRIEF DESCRIPTION OF THE DRAWINGS

Other objects, advantages and novel features of the present invention will become apparent from the following detailed description of the invention, given by way of example only, when considered in conjunction with the accompanying drawings, in which:

FIG. 1 is a high level block diagram of a gas sensing system of the invention;

FIG. 2 is a perspective view of a NOx gas sensor including a MOS sensor ceramic chip wire bonded to pins in a package base;

FIG. 3 is an electrical schematic of the sensor transducer;

FIG. 4 is a plot of resistance vs. time in response to 50 ppm NO₂ in a reduced oxygen environment.

FIG. 5 is a plot showing response to NO in a reduced oxygen environment;

FIG. 6 is a diagram showing a measurement circuit for testing.

FIG. 7 is a diagram showing a test bench assembly for testing; and

FIG. 8 is a plot showing response of a NOx sensor to a synthetic combustion environment at 500° C.

FIG. 9 is a plot showing response of the NOx sensor to varying O₂ levels at 500° C.

### DETAILED DESCRIPTION OF THE EMBODIMENTS

FIG. 1 is a high level block diagram of a NOx gas sensing system 1 of the invention, having a sense element 2 adjacent a heater element 3. The system 1 comprises a heater controller 4, a circuit 5 for gas sensor conditioning, and a microcontroller 6. The transducer consists of the two-terminal sense element 2, and the two-terminal heater element 3 which is controlled so as to maintain the sense element 2 at the optimum operating temperature. The sense element 2 has its impedance modulated according to the concentration of the exposed gas. The gas sensor conditioning electronics 4, 5, and 6 monitor variations in the sensor element 2 impedance. These resistance or impedance variations when combined with calibration algorithms give a measure of value of the target gas concentration. The heater controller 4 monitors the sense element 2 temperature and controls the power of heater 3 so as to maintain optimum operating conditions. The microcontroller 6 with non volatile memory (NVM) stores calibration coefficients determined at manufacturing and implements a number of data correction algorithms.

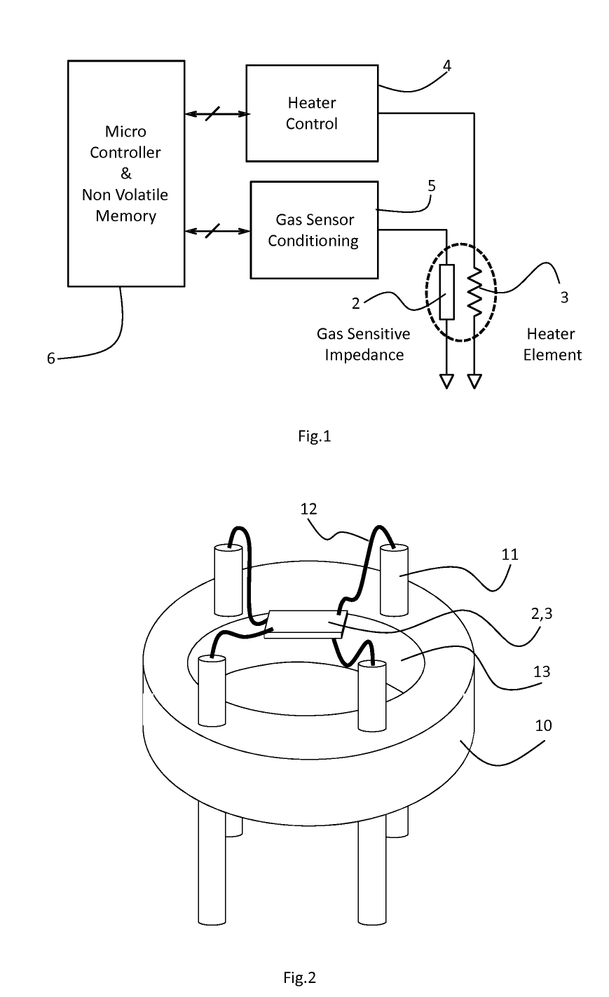

FIG. 2 shows one exemplary physical arrangement of a discrete transducer with the MOS sensor element 2 and the heating element 3 supported from base 10 having pins 11 linked to the transducer (sense element 2 and heater element 3) by wire bonds 12. The sense element 2 has a heated sensor substrate which is thermally isolated from the base 10 as it is suspended in midair. Heat loss is primarily by convection from the element 2 surface and by conduction through the bond wires 12. The electronic circuits 4-6 are on a separate PCB connected to the transducer via the pins 11. The base 10 is of plastics material and has a recess 13 under the transducer 2, 3. Other configurations of base are possible depending on the application. For example, the base may have a through hole aligned with the transducer for through-flow of a gas. It will be recognized that the techniques described herein are not limited to such physical arrangement and other base arrangements and circuitry may be used while still obtaining the benefits of the techniques disclosed herein.

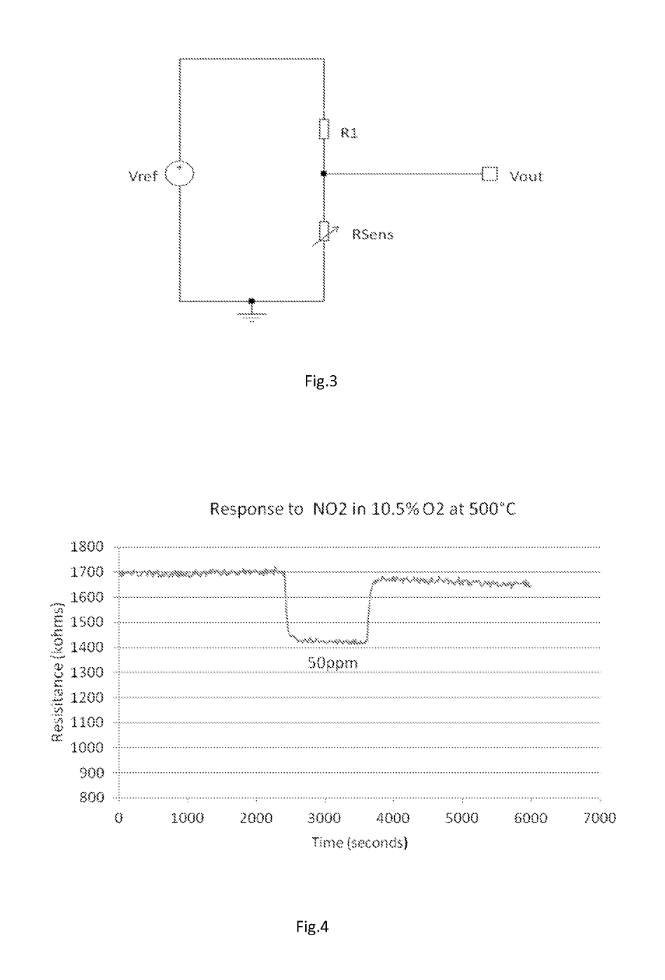

FIG. 3 shows a circuit diagram for a measurement circuit using a potential divider arrangement, in which the sense element 2 provides the resistance RSens. R1 is provided as the series resistor in this arrangement. It will be recognized that a wide range of circuit diagrams may be alternatively used while still obtaining the benefits of the techniques disclosed herein.

Interface Electronics 4, 5 and Algorithms

The sense element 2 is thermally isolated, suspended in air by its bond-wires 12 (FIG. 2) and its temperature is controlled by means of a resistive heater element. The heater control circuit 4 directs current through the heater element 3. Feedback is obtained by monitoring the heater resistance and the embedded microcontroller 6 extrapolates the corresponding temperature using the known resistance-temperature profile of the heater element 3. In this way, the optimum operating conditions can be maintained. The gas sensor conditioning circuitry 5 monitors variations in the sense element 2 resistance and capacitance, and digitizes this data for further digital signal processing by the microcontroller 6.

Formulation and Demonstration of the NOx Gas-Sensitive Material

The gas-sensitive material of the element 2 is based on a BaSnO3-containing multiphase oxide mixture for the purposes of detecting NOₓ. The gas-sensitive coating is comprised of BaSnO3 and at least one phase from the group (ii) CuO, Bi₂O₃, Sb₂O₃, Sb₂O₅, La₂O₃, Cr₂O₃, Fe₂O₃, NiO, TiO₂ to generate the advantageous gas sensing behaviour. Optionally for the purposes of improving response kinetics and providing additional immunity to contaminant gases, 0-10 wt % of dopants from the group (iii) Pt, Pd, Ag, Au or their compounds may be present.

### EXAMPLES

The gas-sensitive material was prepared by mixing commercial grade BaSnO3 powder (Cerac, 325 mesh) with commercial grade CuO powder (Aldrich, coarse grade) in the ratio 90 wt % (72.55 mol %):10 wt % (27.45 mol %) by sieving 3 times through a 63 μm mesh. The powdered mixture was converted into a screen-printable ink, by mixing it with a vehicle based on 5 wt % ethyl cellulose dissolved in dibutyl propane ether using a palette knife and tile, such that the solids loading was 55 wt %.

The gas sensor is then fabricated using a 250 μm thick 2 m×2 m aluminium oxide chip with one side a serpentine platinum heater track and on the other side an interdgitated gold electrode pattern (65 μm electrode digit spacing), upon which an 80 μm thick BaSnO₃—CuO layer was screen-printed. The sensor chip was mounted onto a 4-pinned base by means of welding platinum wires between the chip bond pads and the pin heads.

Control of the sensor temperature was achieved by incorporating the heater into a constant-resistance Wheatstone bridge circuit arrangement. Using this set-up, the resulting sensor was heated to 650° C. for 1 hour and then the temperature reset to 600° C. The output of the sensor was measured in resistance mode. In the measurement circuit used, the sensor formed a resistive element in a potential divider circuit, in which the reference voltage (Vref) was a stable 1.5V and an appropriate series resistor (R1) chosen in order to drop a suitable voltage across the sensor (RSens). The output voltage (Vout) from the potential divider is amplified, digitised and logged by a microcontroller. A schematic of this arrangement is shown in FIG. 3.

### Laboratory Tests

### Examples 1 and Example 2

The sensor was installed in a laboratory gas test rig comprising a computer-controlled multi-port glass cell, with a dedicated signal measurement circuit and a heater control circuit.

The freshly prepared sensor was heated to 600° C. for 1 hour and the temperature was reset to 500° C. using the on-chip heater.

The sensor was gas-tested to both NO₂ and NO using the following sequence of gas steps where the relative humidity level of 50% was used throughout.

20 minutes in static air, 20 minutes in flowing 10.5% O2-balance N2, 20 minutes in flowing 50 ppm NO2-10.5% O2-balance N2, 20 minutes in flowing 10.5% O2-balance N2, 20 minutes in static air.

### Example 1

### NO₂ Gas Test

FIG. 4 is a plot showing response of the NOx sensor to 50 ppm NO2 in 10.5% O2-balance N2 in 50% relative humidity.

### Example 2

### NO Gas Test

The same sequence of gas steps as for NO2 test was used, except instead of 20 minutes in flowing 50 ppm NO2, 10 minutes in flowing 300 ppm NO-10.5% O2-balance N2, followed by 10 minutes in flowing 200 ppm NO-10.5% O2-balance N2 was used.

FIG. 5 shows the resulting response of the sensor to 300 ppm and 200 ppm NO in 10.5% O2-balance N2 in 50% relative humidity.

### Synthetic Combustion Tests

### Example 3 and Example 4

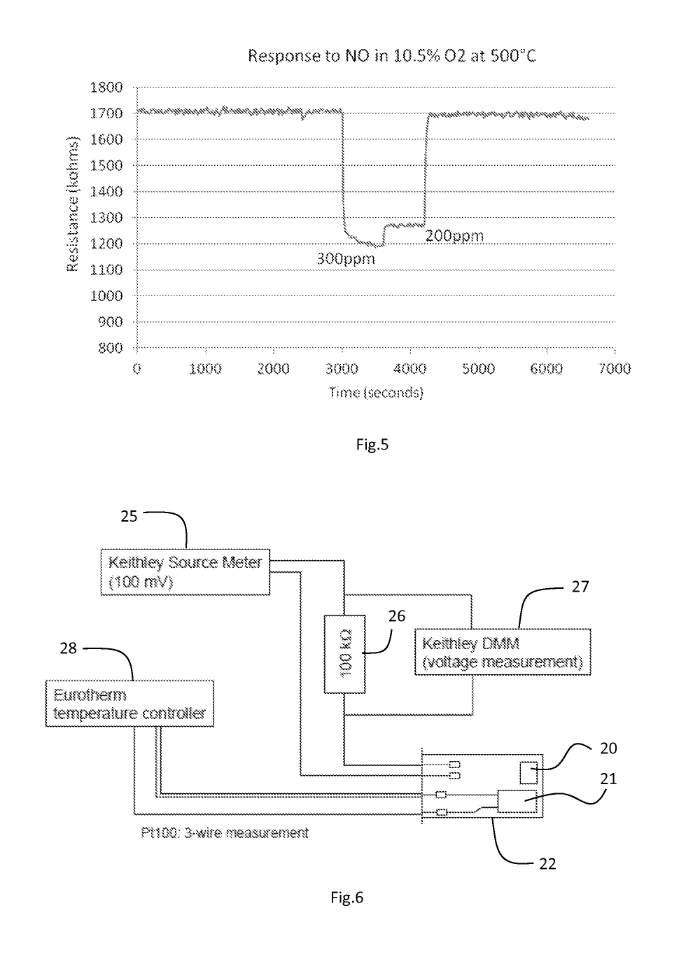

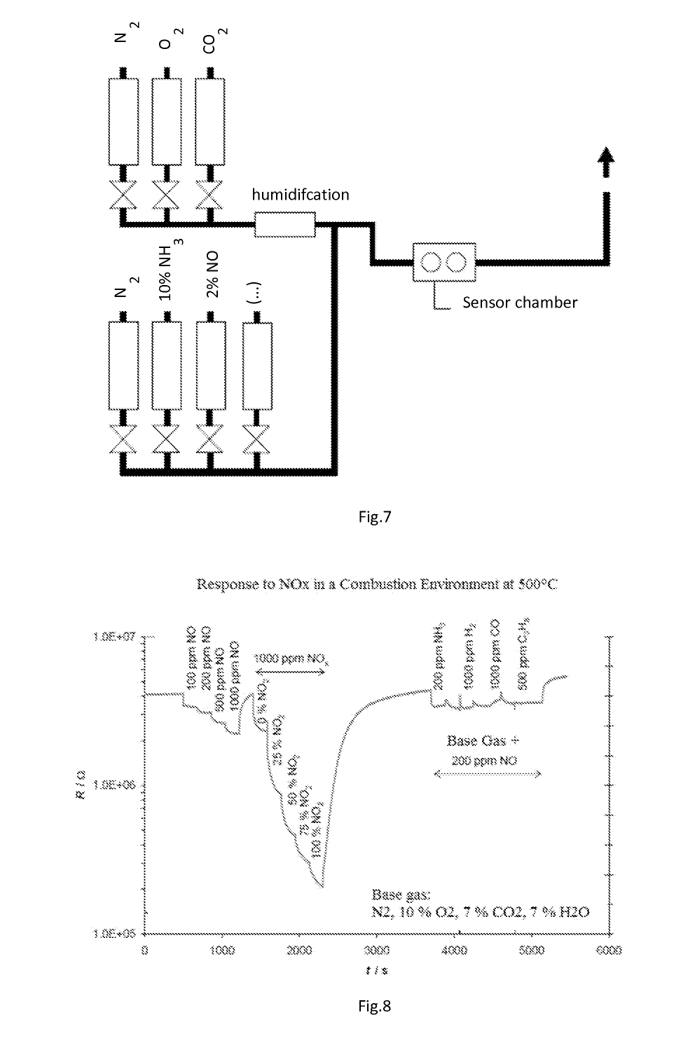

The sensor chips were prepared as for those for the laboratory tests but were then mounted on a carrier ceramic plate as depicted in FIG. 6, in which there are a sense element 20 and a temperature sensor 21 on a ceramics substrate and a heater underneath. The sense element 20 and a reference temperature sensor 22 were located at one end of the plate. Gold tracks to provide connections with the measurement and heater control circuits ran the length of the plate, and were held in place by cement. The plate was encased in a stainless steel tube with the part of the plate containing the sensor standing proud of the casing. This arrangement was then encased in an outer threaded jacket which screwed into the test chamber. As the flow rate was 10 litres/min, a porous cap was placed over the sensor to provide protection. The measurement circuit arrangement is also shown in FIG. 6 while the experimental layout for the test bench assembly is depicted in FIG. 7. FIG. 6 shows use of a Keithley source meter, a 100 kOhm resistance 26, a Keithley DMM meter 27 for voltage measurement, and a temperature controller 28.

The synthetic combustion environment generated specifically;
NOx concentrations with the relative amounts of the constituent NO and NO₂ gases differing
The high humidity levels encountered in hot flues
The worst case levels of contaminant combustion gases, NH₃, H₂, CO, C₃H₈.
Variable O₂ levels from 0.1-10%.
A base gas composition of N₂, 10% O₂, 7% CO₂ and 7% H₂O was used throughout and the sensor operating temperature was 500° C.

### Example 3

The following test sequence using was used.

0-530 seconds 0 ppm NOx
535-705 seconds 100 ppm NO
710-880 seconds 200 ppm NO
885-1055 seconds 500 ppm NO
1060-1230 seconds 1000 ppm NO
1235-1415 seconds 0 ppm NOx
1420-1590 seconds 1000 ppm NO
1595-1765 seconds 750 ppm NO, 250 ppm NO₂
1770-1940 seconds 500 ppm NO, 500 ppm NO₂
1945-2115 seconds 250 ppm NO, 750 ppm NO₂
2120-2290 seconds 0 ppm NO, 1000 ppm NO₂
2295-3765 seconds 0 ppm NOx
3770-3940 seconds 200 ppm NO, 200 ppm NH₃
3945-4115 seconds 200 ppm NO
4120-4290 seconds 200 ppm NO, 1000 ppm H₂
4295-4500 seconds 200 ppm NO
4505-4680 seconds 200 ppm NO, 1000 ppm CO
4685-4850 seconds 200 ppm NO
4855-5030 seconds 200 ppm NO, 500 ppm C₃H₈
5035-5210 seconds 200 ppm NO
5215-5530 seconds 0 ppm NOx

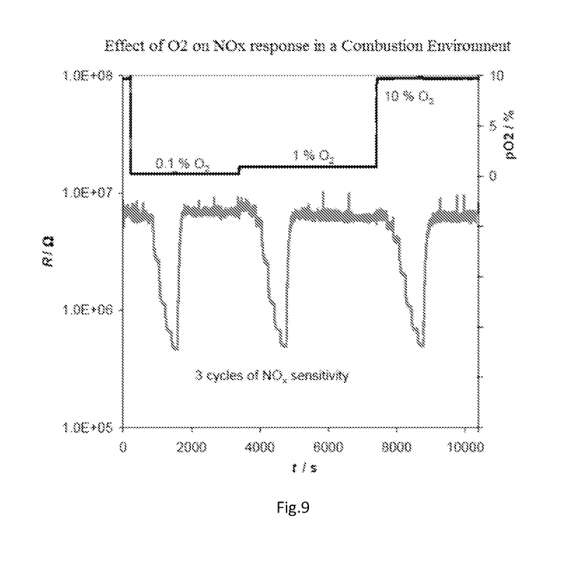

FIG. 8 shows that the sensor is more sensitive to NO₂ compared to NO. It also shows that the sensor is highly selective to NOx, responding preferentially to NOx in the presence of worst-case concentrations of exhaust contaminant gases.

### Example 4

### Effect of Variable O₂

To explore the effect of O₂ on the response of the sensor to NOx, the sensor was exposed to a constant level of NOx, but with altering NO: NO₂ levels, at three different O₂ concentration, 0.1%, 1% and 10%. Thus for each concentration of O₂ beginning with 0.1%, the following test sequence was used:

### 0 ppm NOx

### 100 ppm NO

### 400 ppm NO

### 300 ppm NO/100 ppm NO2

### 200 ppm NO/200 ppm NO2

### 100 ppm NO/300 ppm NO2

### 400 ppm NO2

It can be seen in FIG. 9 that at 0.1 and 1% O₂, there is a similar response to NOx while at the more commonly encountered higher O₂ level of 10%, the sensor shows increased sensitivity to NO in the absence of NO₂ and/or at levels of NO₂ below 200 ppm.

It will be appreciated that the invention provides a NOx-sensing material and sensing system incorporating such a material which is particularly effective. For example, FIG. 8 shows the performance of the NOx sensor in the synthetic combustion environment of N₂, 10% O₂, 7% H₂O and 7% CO₂. The sensor is exposed to varying levels of NOx, varying ratios of NO:NO₂ and to high concentrations of typical contaminant gases, NH₃, H₂, CO and C₃H₈. FIG. 9 is shows the performance of the NOx sensor in the synthetic combustion environment of N₂, 7% H₂O.

The invention is not limited to the embodiments described.

What is claimed is:

1. A gas-sensitive material for detecting NOₓ, the material comprising:
from about 45 mol % to about 95 mol % of BaSnO₃, and
from about 5 mol % to about 55 mol % of one or more oxides, the one more oxides comprising at least one of CuO, Cr₂O₃, Fe₂O₃, MnO, NiO, CoO, Bi₂O₃, Sb₂O₃, Sb₂O₅, WO₃, ZnO, SnO₂, or any combination thereof.

2. The gas-sensitive material as claimed in claim 1, wherein the material further comprises from about 0 to about 10 wt % of one or more dopants, the one or more dopants comprising at least one of Pt, Pd, Ag, Au, their compounds, or any combination thereof.

3. The gas-sensing material as claimed in claim 1, wherein the material further comprises a catalytically active oxide or precious metal material to provide increased stability and additional protection against nuisance gases.

4. The gas-sending material of claim 1, further comprising from about 0.01 to about 10 wt % Pt.

5. The gas-sensing material of claim 1, wherein the material includes a mixture of BaSnO₃ and CuO such that CuO is present in an amount of from about 25 to about 50 mol %.

6. The gas-sensing material of claim 1, wherein the material has grain sizes in the nano-particulate range of from about 1 to about 400 nm or in the micro particulate range of from about 0.4 μm to about 40 μm.

7. A NOx-detecting transducer comprising a heating element, and a sense element upon which is disposed a gas sensitive material as a thick or thin film open to the atmosphere, said gas sensitive material comprising:
from about 45 mol % to about 95 mol % of BaSnO₃, and
from about 5 mol % to about 55 mol % of one or more oxides, the one more oxides comprising at least one of CuO, Cr₂O₃, Fe₂O₃, MnO, NiO, CoO, Bi₂O₃, Sb₂O₃, Sb₂O₅, WO₃, ZnO, SnO₂, or any combination thereof.

8. The transducer of claim 7, wherein the sense elements are configured as a co-planar array of interdigitated fingers with the gas-sensitive material coated thereupon.

9. The transducer of claim 7, further comprising a micro-hotplate substrate, or a silicon-on-insulator, or a SiC substrate, or an oxide ceramic substrate.

10. The transducer of claim 7, wherein the sense elements are configured as a co-planar array of interdigitated fingers with a spacing in the range of 60 μm to 70 μm.

11. The transducer of claim 7, wherein the gas-sensitive coating is screen-printed to a thickness in the range of 140 μm to 160 μm.

12. The transducer of claim 7, wherein the sense element includes gold or another precious metal.

13. The transducer of claim 7, wherein the heating element comprises platinum.

14. A method for detecting changes in NOₓ concentration in an atmosphere with a transducer, the method comprising:
providing a transducer comprising a heating element, and a sense element upon which is disposed a gas sensitive material as a thick or thin film open to the atmosphere;
contacting the atmosphere with the gas-sensitive material of the transducer; and
measuring changes in at least one of the conductivity, resistance, capacitance, or impedance of said sense element;
the gas sensitive material comprising from about 45 mol % to about 95 mol % of BaSnO₃, and from about 5 mol % to about 55 mol % of one or more oxides, the one more oxides comprising at least one of CuO, Cr₂O₃, Fe₂O₃, MnO, NiO, CoO, Bi₂O₃, Sb₂O₃, Sb₂O₅, WO₃, ZnO, SnO₂, or any combination thereof.

15. The method of claim 14, the atmosphere being a reducing atmosphere, the method comprising detecting changes in NOₓ concentration in the range of from about 1 to about 2500 ppm NOₓ.

16. The method of claim 14, wherein said sense element has an operating temperature in the range from about 100° C. to about 700° C.

17. The method of claim 14, wherein said sense element has an operating temperature in the range from about 500° C. to about 650° C. and preferably 100° C. to 400° C. for gas-fuelled heating exhaust environments.

18. The method of claim 14, wherein said sense element has an operating temperature in the range from about 100° C. to about 400° C. for gas-fuelled heating exhaust environments.

19. The method of claim 14, wherein the environment is an exhaust from a combustion engine.

20. A method for preparing a NOx-detecting transducer, comprising:
providing a heating element and a sense element for the transducer; and
depositing gas-sensitive material upon the sense element by a technique that comprises at least one of screen-printing, stencil printing, spin-coating, sputtering, ink-jet printing, or any combination thereof;
the gas sensitive material comprising from about 45 mol % to about 95 mol % of BaSnO₃, and from about 5 mol % to about 55 mol % of one or more oxides, the one more oxides comprising at least one of CuO, Cr₂O₃, Fe₂O₃, MnO, NiO, CoO, Bi₂O₃, Sb₂O₃, Sb₂O₅, WO₃, ZnO, SnO₂, or any combination thereof.

21. A NOx gas sensor comprising:
a transducer comprising a heating element and a sense element upon which is disposed a gas sensitive material as a thick or thin film open to the atmosphere;
a drive interface adapted to provide a voltage across said sense element;
a sense interface adapted to monitor an electrical parameter of the sense element; and
a processor adapted to process the monitored parameter;
the gas sensitive material comprising from about 45 mol % to about 95 mol % of BaSnO₃, and from about 5 mol % to about 55 mol % of one or more oxides, the one more oxides comprising at least one of CuO, Cr₂O₃, Fe₂O₃, MnO, NiO, CoO, Bi₂O₃, Sb₂O₃, Sb₂O₅, WO₃, ZnO, SnO₂, or any combination thereof.
